(19) United States
(12) Patent Application Publication
(10) Pub. No.: US 2007/0278385 A1
(43) Pub. Date: Dec. 6, 2007

(54) Computer Microscope

(76) Inventor: Donald Spector, New York, NY (US)

Correspondence Address: DIEHL SERVILLA LLC, 77 BRANT AVE, SUITE 210, CLARK, NJ, 07066, US

(21) Appl. No.: 11/425,241

(22) Filed: Jun. 20, 2006

Related U.S. Application Data
(60) Provisional application No. 60/809,320, filed on May 30, 2006.

(51) Int. Cl. H01L 27/00

(52) U.S. Cl. 250/208.1; 250/239

(57) ABSTRACT

A system and method of providing a computer microscope is disclosed. The system includes a portable enclosure that encloses an interior, a source of light mounted on the enclosure that illuminates the interior, an imager mounted on the enclosure that can generate an image of the interior, wherein the imager has no image viewer and a communication channel that can provide the image on an output. A computer is connected to the communication channel to be able to display the images from the imager.

### CROSS-REFERENCE TO RELATED APPLICATIONS

This application claims the benefit of U.S. Provisional Application No. 60/809,320, filed May 30, 2006, which is incorporated herein by reference.

### BACKGROUND OF THE INVENTION

Microscopes created enlarged images of an object being examined. They have many uses, including the use by students in classroom and labs to educate themselves about a wide range of subjects such as biology and chemistry. Students typically view the image through a viewing mechanism provided by the microscope.

Images can be viewed and processed using computers, such as a personal computer, using available application software. The computer enables images to be viewed and processed in ways that a microscope does not.

An effective combination of a microscope and a computer is needed for the classroom.

### SUMMARY OF INVENTION

In accordance with one aspect of the present invention, an apparatus is provided that includes an enclosure that encloses an interior, a source of light mounted on the enclosure that illuminates the interior, an imager mounted on the enclosure that can generate an image of the interior, and a communication channel that can provide the image on an output.

In accordance with a preferred embodiment of the present invention, the imager has no image viewer

In accordance with one aspect of the present invention, the interior has a limited size to accommodate the enclosure of small organisms, such as ants. For example, the interior can be 10 cubic feet or less. It can also be 5 cubic feet or less as well as 2 cubic feet or less. In accordance with one embodiment of the present invention, the interior has an enclosed space of one cubic foot or less.

In accordance with an aspect of the present invention, the apparatus includes a display connected to the output that can display the image.

In accordance with another aspect of the present invention, the apparatus includes a display connected to the output that can display the image. The computer can be connected to the communication channel via an internet connection.

In accordance with a further aspect of the present invention, the computer can process the image. For example, the computer can zoom in or out on the image.

In accordance with another aspect of the present invention, the communication channel is or includes a universal serial bus (USB) circuit.

The apparatus of the present invention can further include a living organism which is placed in the interior.

In accordance with a further aspect of the present invention, the computer can provide an input through the communication channel to control the imager, the source of light or both devices. The computer can also provide power to the imager and the light source through the communications channel.

In accordance with another aspect of the present invention, the computer can generate a screen saver from the image received from the imager.

Corresponding methods are also contemplated by various aspects of the present invention.

### BRIEF DESCRIPTION OF THE FIGURES

FIG. 1 illustrates a system in accordance with one aspect of the present invention.

FIG. 2 illustrates an enclosure for an imager in accordance with an aspect of the present invention.

FIG. 3 illustrates a circuit in accordance with an aspect of the present invention.

### DETAILED DESCRIPTION

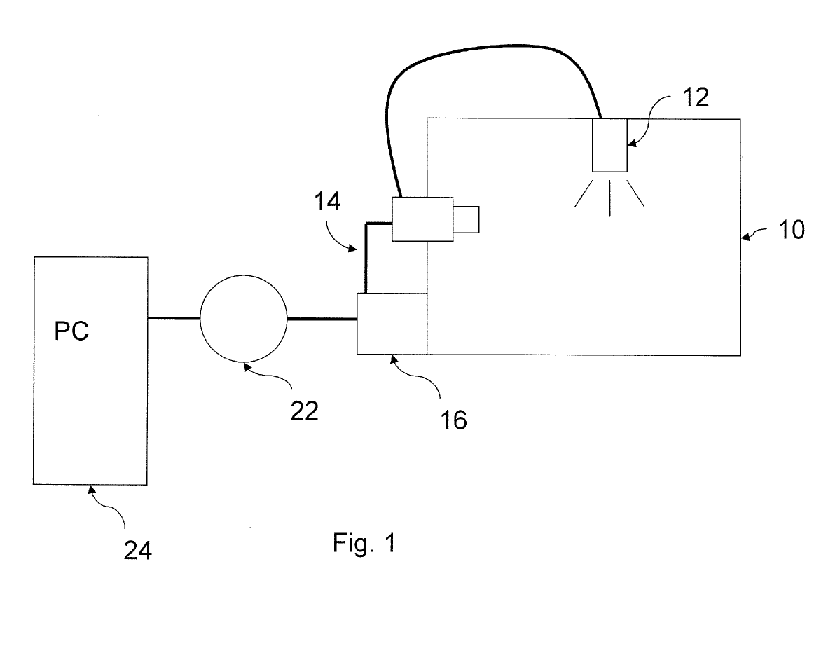

FIG. 1 illustrates a system in accordance with one aspect of the present invention. An enclosure 10 houses a source of light 12, an imager 14 and a communication channel 16.

In accordance with one aspect of the present invention, the enclosure 10 is portable to allow it to be carried from area to area. Thus, for example, a teacher could move the enclosure 10 from classroom to classroom or from seat to seat to enable different students to use the system of the present invention. In accordance with another aspect of the present invention, the enclosure 10 preferably has a limited size to accommodate the enclosure of small organisms, such as ants. Other living organisms can also be studied. For example, bees, caterpillars, moths, frogs and the like can be studied. The interior can be 10 cubic feet or less. It can also be 5 cubic feet or less as well as 2 cubic feet or less. In accordance with one embodiment of the present invention, the interior has an enclosed space of one cubic foot or less. The size selected depends on the size of the ecosystem to be studied.

The enclosure can be made of metal or wood or any other suitable material. The enclosure 10 preferably, but not necessarily, provides a complete enclosure around an interior to keep living organisms inside. Air holes can be provided that are large enough to let air in the enclosure 10 but small enough to keep the organisms inside the enclosure 10. The enclosure 10 may include a removable component to allow access inside the enclosure 10. For example, a removable top can be provided.

The source of light 12 can be any suitable illumination means that illuminates the interior of the enclosure 10 to allow adequate viewing of the contents of the enclosure 10. For example, it can be an incandescent lamp, a fluorescent lamps, light emitting diodes and combinations thereof. A power switch can be provided on the source of light 12 or on the enclosure 10 so that the light can be selectively turned on or off. Alternatively, as will be explained in greater detail, the power to the source of light 12 can be provided by a device connected to the communication channel 16.

The imager 16 can be any suitable device that provides an image, preferably a digital image. The imager 14 preferably includes a charge coupled device (CCD), such as those found in today's digital cameras. In accordance with one aspect of the present invention, the imager 14 is not a microscope. In accordance with a further aspect of the present invention the imager 14 does not have viewing mechanism. This includes optical viewing means that are typically found on digital cameras and on microscopes. It also includes LCD screens, such as are typically found on digital cameras. This minimizes the expense associated with the present invention.

The imager 14 preferably includes a lens that allows viewing of the entire interior of the enclosure 10. The imager 14 may also be mounted in the enclosure 10 to allow movement of the imager 14 to view particular areas inside the enclosure 10. The movement may be controlled manually or electronically.

The imager 14 can include various controls, such as a zoom in/zoom out capability and power. It can also include nightshot circuitry enabling the capture of images in low light scenarios. Essentially, controls found on today's digital cameras can be provided in the imager 14. Controls can also be provided to move the direction of the imager 14. The inputs to control the imager 14 can be placed on the imager 14 external to the enclosure 14. Alternatively, the inputs to control the imager 14 may be provided from a device through the communication channel 16 from a computer 24.

More than one imager 14 can also be provided to allow the contents of the interior of the enclosure 10 to be viewed from more than one angle. Also, a three dimensional effect can be created with more than one imager 14.

An external device 24 is connected to the communication channel 16 either directly or via a connection to the internet 22. The external device 24 can either be a display or a computer, such as a personal computer, with a display. Direct connection can be provided if the system is being used in a classroom. The internet connection can be used to allow students to view the images being generated while at home.

The communication channel 16 is preferably a universal serial bus (USB). The protocol for USB is well known. The communication channel 16 can also be a wireless transceiver or a wireless transmitter device.

In accordance with one aspect of the present invention, the images are generated in the enclosure 10 and transmitted via the communication channel 16 to the external device 24. Thus, information

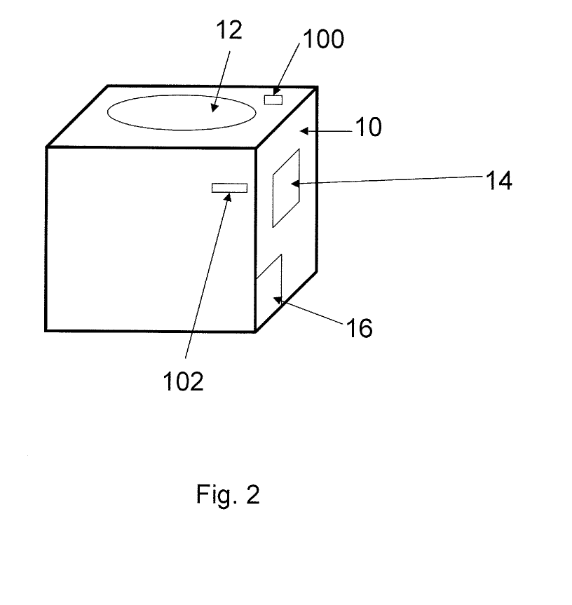

FIG. 2 illustrates the enclosure 10 in accordance with one aspect of the present invention. The source of light 12 is preferably mounted in the top of the enclosure 10. The mounted may be to the interior wall of the enclosure 10 or may be such that a portion of the source of light 12 extends from the enclosure. Controls 100 for the source of light 12 may be provided on the enclosure 10. A power cord can also be provided from the enclosure 10 to power the light source 12 and the imager 14, or power can be provided by battery or from an external device connected through the communications channel 16.

The imager 14 is preferably mounted in a side of the enclosure 10 or in the top of the enclosure 10. Controls 102 for the imager 14 are provided outside the enclosure 10.

The communications channel 16 is provided on the enclosure 10. The wires connecting the communications channel 16 to the source of light 12 and to the imager 14 can be provided on the external surface or the internal surface of the enclosure 10.

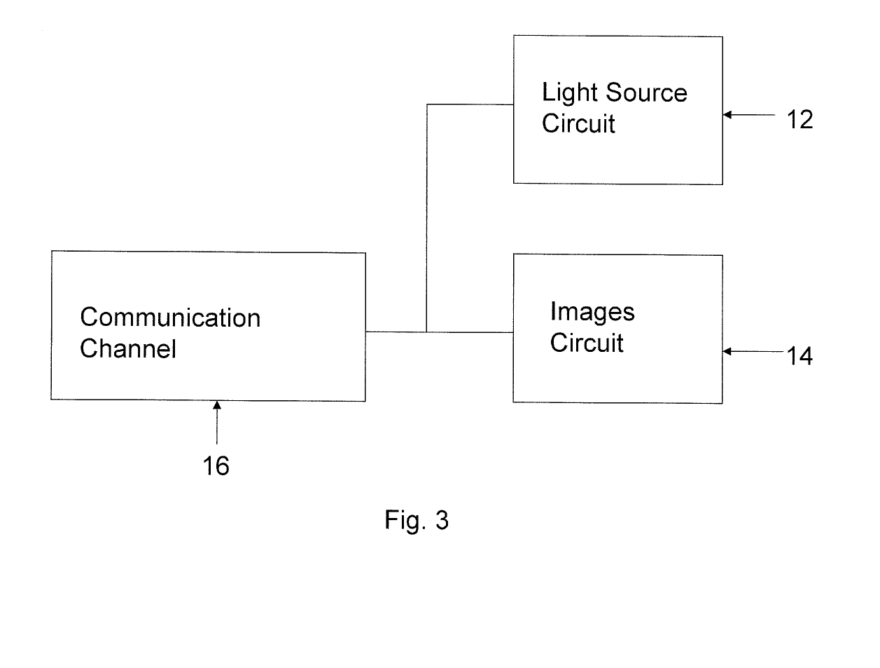

FIG. 3 illustrates a circuit in accordance with one aspect of the present invention. The communications channel 16 is connected to the source of light 12 and to the imager 14. Image signals are provided from the imager 14 to the communications channel 16 for output from the enclosure 10. Control signals can be provided from a device external to the enclosure through the communications channel 16 to the imager 14 and to the light source 12. Power can similarly be provided from a device external to the enclosure through the communications channel 16 to the imager 14 and to the light source 12.

The present invention also contemplates a method. The method includes the steps of illuminating an interior of an enclosure, generating an image of the interior with an imager, and transmitting the image from the enclosure through a communication channel. The size of the interior can be limited as described before. Further, in accordance with one aspect of the present invention, the imager has no image viewer, so that the method in accordance with this aspect of the present invention limits the use of the imager.

The image is received at a display connected to the communication channel and the image is displayed at the display.

Alternatively, a computer can be connected to the communications channel and the image can be transmitted from the imager 14 through the communications channel 16 to the computer, and then displayed on a display of the computer. The computer can be any type of computer, such as a personal computer.

The transmission of the image can be directly from the communications channel 16 to the computer, or can be through the internet. Thus, the computer can be located in a classroom in a school in which the enclosure 10 is located or can be remote from the enclosure 10. This enables a student to view the contents of the enclosure 10 on a computer located at home.

The computer can also process the image. The processing can include zooming in, zooming out or any other editing or processing provided by any well known image processing application package available for use on a computer.

In accordance with another aspect of the present invention, the computer processes the image. The processing includes zooming in and zooming out on the image. The processing can also include brightness controls, contrast controls, color controls and other editing and processing features found in today's image processing application software.

In another step in accordance with another aspect of the present invention, a living organism is placed in the interior of the enclosure 10.

In accordance with a further aspect of the method of the present invention, a computer connected to the imager 14 and the light source 12 through the communication channel 16 provides an input through the communication channel to control the imager 14 and to control the source of light 12. All of the controls needed for the light source 12 and the imager 14 can either be provided on a control panel 100 and 102 on the enclosure 10 or by a remotely connected computer 24. In accordance with a further aspect of the method of the present invention, the computer 24 provides power to the imager 14 and/or the light source 12 through the communications channel 16.

The method further includes the step of generating a screen saver image from one or more of the images generated by the imager 14 and displaying the screen saver on the computer 24.

While this invention is satisfied by embodiments in many different forms, there are shown in the drawings and herein described in detail, embodiments of the invention with the understanding that the present disclosure is to be considered as exemplary of the principles of the present invention and is not intended to limit the scope of the invention to the embodiments illustrated. The scope of the invention is measured by the appended claims and the equivalents.

1. An apparatus, comprising:
a portable enclosure that encloses an interior;
a source of light mounted on the enclosure that illuminates the interior;
an imager mounted on the enclosure that can generate an image of the interior, wherein the imager has no image viewer; and
a communication channel that can provide the image on an output.

2. The apparatus of claim 1, comprising a display connected to the output that can display the image.

3. The apparatus of claim 1, comprising a computer with a display connected to the output that can display the image.

4. The apparatus of claim 3, wherein the computer is connected to the communication channel via an internet connection.

5. The apparatus of claim 3, wherein the computer can process the image.

6. The apparatus of claim 4, wherein the computer can zoom in or out on the image.

7. The apparatus of claim 3, wherein communication channel includes a universal serial bus (USB) circuit.

8. The apparatus of claim 1, comprising a living organism in the interior.

9. The apparatus of claim 3, wherein the computer provides an input through the communication channel to control the imager.

10. The apparatus of claim 3, wherein the computer provides an input through the communication channel to control the source of light.

11. The apparatus of claim 7, wherein the computer provides power to the imager and the light source through the communications channel.

12. The apparatus of claim 3, wherein the computer generates a screen saver based on the image.

13. A method, comprising:
illuminating an interior of a portable enclosure;
generating an image of the interior with an imager, wherein the imager has no image viewer;
transmitting the image from the enclosure through a communication channel.

14. The method of claim 13, comprising receiving the image at a display connected to the communication channel and displaying the image.

15. The method of claim 14, comprising receiving the image at a computer connected to the communication channel and displaying the image at a display.

16. The method of claim 15, wherein the computer is connected to the communication channel via an internet connection.

17. The method of claim 15, comprising the computer processing the image.

18. The method of claim 14, comprising placing a living organism in the interior.

19. The method of claim 14, comprising the computer providing an input through the communication channel to control the imager.

20. The method of claim 14, comprising the computer providing an input through the communication channel to control the source of light.

21. The method of claim 20, comprising the computer providing power to the imager and the light source through the communications channel.

22. The method of claim 15, wherein the computer generates a screen saver based on the image.
